(19) United States
(12) Patent Application Publication
(10) Pub. No.: US 2023/0416911 A1
(43) Pub. Date: Dec. 28, 2023

(54) SELECTIVE DEPOSITION OF SILICON AND OXYGEN CONTAINING DIELECTRIC FILM ON DIELECTRICS

(71) Applicant: VERSUM MATERIALS US, LLC, TEMPE, AZ (US)

(72) Inventors: RAVINDRA KANJOLIA, NORTH ANDOVER, MA (US); GUO LIU, SAN JOSE, CA (US); MARK POTYEN, SHEBOYGAN, WI (US); JACOB WOODRUFF, LEXINGTON, MA (US); BHUSHAN ZOPE, SAN JOSE, CA (US); XINJIAN LEI, VISTA, CA (US)

(21) Appl. No.: 18/253,169

(22) PCT Filed: Nov. 15, 2021
(86) PCT No.: PCT/US2021/059412

§ 371 Date: May 16, 2023

Related U.S. Application Data
(60) Provisional application No. 63/114,165, filed on Nov. 16, 2020.

(51) Int. Cl. C23C 16/455; H01L 21/02; C23C 16/40; C23C 16/04

(52) U.S. Cl. CPC C23C 16/45527; H01L 21/02164; H01L 21/02126; H01L 21/0214; H01L 21/02211; H01L 21/0228; H01L 21/02304; C23C 16/401; C23C 16/04; C23C 16/0227

(57) ABSTRACT

A thermal atomic layer deposition method for selectively deposition of silicon and oxygen containing dielectric film selected from silicon oxide or carbon doped silicon oxide abundantly on a dielectric surface but not less on a metal surface employing a silicon precursor having at least three isocyanato ligands.

### CROSS-REFERENCE TO RELATED APPLICATIONS

This application is a National Stage filing under 35 U.S.C. 371 of International Patent Application No. PCT/US2021/059412, filed Nov. 15, 2021, which claims priority to U.S. Patent Application having Ser. No. 63/114,165 filed on Nov. 16, 2020. The entire contents of these applications are incorporated herein by reference in their entirety.

### FIELD OF THE INVENTION

Described herein is a composition and method for the fabrication of an electronic device. More specifically, described herein are compounds, and compositions and methods comprising same, for selectively depositing a silicon and oxygen-containing film such as silicon oxide, silicon oxynitride, carbon doped silicon oxide, or carbon doped silicon oxynitride on a dielectric, and not on a metal or metal hydride, importantly avoiding/minimizing oxidation of the metal or metal hydride layer.

### BACKGROUND OF THE INVENTION

There is a need in the art to provide a composition and method using non-halogenated precursors and mild oxidant for depositing silicon and oxygen-containing films such as silicon oxide or carbon doped silicon oxide for certain applications in the semi-conductor industry.

U.S. Pat. Nos. 7,084,076 and 6,992,019 describe methods for deposition of a silicon dioxide film using atomic layer deposition (ALD), wherein a halogen- or NCO-substituted siloxane is used as a Si source.

US Publ. No. 2013/022496 teaches a method of forming a dielectric film having Si—C bonds on a semiconductor substrate by ALD, which includes: (i) adsorbing a precursor on a surface of a substrate; (ii) reacting the adsorbed precursor and a reactant gas on the surface; and (iii) repeating steps (i) and (ii) to form a dielectric film having at least Si—C bonds on the substrate.

US Publ. No. 2014/302688 describes a method for forming a dielectric layer on a patterned substrate that may include combining a silicon-and-carbon-containing precursor and a radical oxygen precursor in a plasma free substrate processing region within a chemical vapor deposition chamber. The silicon-and-carbon-containing precursor and the radical oxygen precursor react to deposit the flowable silicon-carbon-oxygen layer on the patterned substrate.

US Publ. No. 2014/302690 describes methods for forming a low-k dielectric material on a substrate. The methods may include the steps of producing a radical precursor by flowing an unexcited precursor into a remote plasma region, and reacting the radical precursor with a gas-phase silicon precursor to deposit a flowable film on the substrate. The gas-phase silicon precursor may include at least one silicon-and-oxygen containing compound and at least one silicon-and-carbon linker. The flowable film may be cured to form the low-k dielectric material.

US Publ. No. 2014/051264 describes methods of depositing initially flowable dielectric films on substrates. The methods include introducing silicon-containing precursor to a deposition chamber that contains the substrate. The methods further include generating at least one excited precursor, such as radical nitrogen or oxygen precursor, with a remote plasma system located outside the deposition chamber. The excited precursor is also introduced to the deposition chamber, where it reacts with the silicon-containing precursor in a reaction zone deposits the initially flowable film on the substrate. The flowable film may be treated in, for example, a steam environment to form a silicon oxide film.

PCT Publ. No. WO11043139 A1 describes a raw material containing tri-isocyanate silane (HSi(NCO)₃) for forming silicon-containing film.

PCT Publ. No. WO14134476A1 describes methods for the deposition of films comprising SiCN and SiCON. Certain methods involve exposing a substrate surface to a first and second precursor, the first precursor having a formula (X_{y}H_{3-y}Si)zCH_{4-z}, (X_{y}H_{3-y}Si)(CH₂)(SiXₚH₂₋ₚ)(CH₂)(SiX_{y}H_{3-y}), or (X_{y}H_{3-y}Si)(CH₂)ₙ(SiX_{y}H_{3-y}), wherein X is a halogen, y has a value of between 1 and 3, z has a value of between 1 and 3, p has a value of between 0 and 2, and n has a value between 2 and 5, and the second precursor comprising a reducing amine. Certain methods also comprise exposure of the substrate surface to an oxygen source to provide a film comprising SiCON.

The reference entitled “Quasi-monolayer deposition of silicon dioxide”, Gasser, W, Z. et al., Thin Solid Films, 1994, 250, 213 discloses SiO₂ films that were deposited layer by layer from a new silicon source gas, i.e. tetra-iso-cyanate-silane (Si(NCO)₄).

The reference entitled “Atomic-layer chemical-vapor-deposition of silicon dioxide films with an extremely low hydrogen content”, Yamaguchi, K. et al, Applied Surface Science, 1998, 130, 202 discloses atomic-layer-deposition of SiO₂ with an extremely low H content using Si(NCO)₄ and N(C₂H₅)₃.

The reference entitled “Catalyzed Atomic Layer Deposition of Silicon Oxide at Ultra-low Temperature Using Alkylamine”, Mayangsari, T. et al., reported the catalyzed atomic layer deposition (ALD) of silicon oxide using Si₂Cl₆, H₂O, and various alkylamines.

There is a need in the art to provide a method of deposition of silicon dielectric such as silicon oxide, carbon doped silicon oxide, and carbon doped silicon oxynitride selectively on top of a dielectric surface relative to a metal surface in a semiconductor manufacturing process using a thermal process without strong oxidants such as ozone or oxygen containing plasma.

### BRIEF SUMMARY OF THE INVENTION

The present invention, according to one embodiment, includes a thermal atomic layer deposition method for selectively depositing a silicon oxide, silicon oxynitride, carbon doped silicon oxide, carbon doped silicon oxynitride film onto surface features on a substrate, the method comprising:
a) providing at least one substrate having both a dielectric surface and a metal surface in a reactor,
b) heating the reactor to at least one temperature ranging from ambient temperature to about 350° C. and optionally maintaining the reactor at a pressure of 100 torr or less,
c) introducing into the reactor at least one self-assembled monolayer (SAM) volatile precursor selected from the group consisting of organic thiol compounds to anchor on the metal surface more abundantly than on the dielectric surface,
d) purging any unreacted precursor from the reactor using inert gas,
e) introducing into the reactor a silicon compound selected from the group consisting of tetraisocyanatosilane (TICS), triisocyanatosilane, and triisocyanatomethylsilane, and optionally a catalyst, to deposit the silicon compound on the dielectric surface more abundantly than on the metal surface;
f) purging any unreacted silicon compound from the reactor using inert gas,
g) providing an oxygen source and optionally a catalyst into the reactor to form a silicon and oxygen containing film on the dielectric surface, wherein the catalyst comprises a Lewis base; and
h) purging reactor with purge gas.
   Preferably, the Lewis base is such as pyridine, piperazine, ammonia, or other organic amines including primary amines H₂NR¹, secondary amines HNR¹R², ternary amines R¹NR²R³ wherein each of R¹⁻³ is independently selected from C₁ to C₁₀ alkyl.

### BRIEF DESCRIPTION OF THE DRAWINGS

FIG. 1 shows the thickness of silicon and oxygen containing dielectric film vs number of cycles using tetraisocyanatosilane, water, and trimethylamine as catalyst, demonstrating linear growth behavior.

FIG. 2 shows the thickness of silicon and oxygen containing dielectric film on copper with and without SAM using tetraisocyanatosilane, water, and trimethylamine as catalyst, demonstrating clear selectivity with SAM blocking SiO₂ growth on Cu when SiO₂ thickness on native oxide is below about 120 and loosing selectivity at about 120 Å or thicker.

### DETAILED DESCRIPTION OF THE INVENTION

Described herein are compositions and processes related to selectively deposit on silicon or metal dielectric surface over metal surface in a thermal atomic layer deposition (ALD) or in an ALD-like process, such as without limitation a cyclic chemical vapor deposition process (CCVD) while not on metal surface employing a silicon precursor selected from the group consisting of tetraisocyanatosilane (TICS), triisocyanatosilane, and triisocyanatomethylsilane.

The silicon compound(s) according to the present invention and compositions comprising the silicon precursor compounds are preferably substantially free of halide. As used herein, the term “substantially free” as it relates to halide ions (or halides) such as, for example, chlorides (i.e. chloride-containing species such as HCl or silicon compounds having at least one Si—Cl bond) and fluorides, bromides, and iodides, means less than 5 ppm (by weight) measured by ion chromatography (IC) or inductively coupled plasma mass spectrometry (ICP-MS), preferably less than 3 ppm measured by IC or ICP-MS, and more preferably less than 1 ppm measured by IC or ICP-MS, and most preferably 0 ppm measured by IC or ICP-MS. The silicon compound(s) are preferably substantially free of metal or metal ions such as, Li⁺(Li), Na⁺(Na), K⁺(K), Mg²⁺(Mg), Ca²⁺(Ca) Al³⁺(Al), Fe²⁺(Fe), Fe³⁺(Fe), Ni²⁺(Fe), Cr³⁺(Cr), titanium (Ti), vanadium (V), manganese (Mn), cobalt (Co), nickel (Ni), copper (Cu), or zinc (Zn). As used herein, the term “substantially free” as it relates to Li, Na, K, Mg, Ca, Al, Fe, Ni, Cr, Ti, V, Mn, Co, Ni, Cu or Zn means 5 ppm or less (by weight), preferably less than 3 ppm, and more preferably 1 ppm or less, and most preferably 0.1 ppm or less as measured by ICP-MS. In addition, the silicon compounds having Formula I preferably have purity of 98 wt. % or higher, more preferably 99 wt. % or higher as measured by GC when used as precursor to deposit the silicon and oxygen-containing films.

One embodiment of the invention includes a method of depositing a silicon oxide film having a carbon or/and nitrogen content of less than 1 at. % using at least one silicon compound having isocyanato ligand. Another embodiment of the present invention is directed to the silicon and oxygen containing dielectric film deposited using the composition, and methods described herein, which exhibits an extremely low etch rate, preferably about 0.20 Å/s or less or about 0.15 Å/s or less in dilute HF, while exhibiting variability in other tunable properties such as, without limitation, density, dielectric constant, refractive index, and elemental composition According to a preferred embodiment one silicon precursor is tetraisocyanatosilane (TiCS), which is deposited in the presence of a catalyst and an oxygen source such as water. In this or other embodiments, the catalyst is selected from a Lewis base such as pyridine, piperazine, ammonia, or other organic amines including primary amines H₂NR¹, secondary amines HNR¹R², or ternary amines R¹NR²R³ wherein R¹⁻³ are defined as aforementioned.

Examples of organic amines include but are not limited to trimethylamine, dimethylamine, monomethylamine, triethylamine, diethylamine, monoethylamine, tri-n-propylamine, di-n-propylamine, mono-n-propylamine, tri-iso-propylamine, di-iso-propylamine, mono-iso-propylamine, tri-n-butylamine, di-n-butylamine, mono-n-butylamine, tri-iso-butylamine, di-iso-butylamine, mono-iso-butylamine, and phenyldimethylamine preferably a tertiary amine. In some embodiments, the catalyst is delivered into the reactor using a different gasline, while in other embodiments the catalyst is pre-mixed with the oxygen source with a catalyst concentration ranging from 0.001 to 99.99 wt % and then delivered into the reactor via direct liquid injection (DLI) or bubbling or vapor draw, preferably DLI. The amount of oxygen source such as water in the catalyst is between 0.001 wt. %-99.99 wt. %.

The method described according to an exemplary embodiment comprises:
a) providing at least one substrate having both a dielectric surface and a metal surface in a reactor,
b) heating the reactor to at least one temperature ranging from ambient temperature to about 350° C. and optionally maintaining the reactor at a pressure of 100 torr or less,
c) introducing into the reactor at least one self-assembled monolayer (SAM) volatile precursor selected from the group consisting of organic thiol compounds to predominately anchor on the metal surface while not on the dielectric surface,
d) purging any unreacted precursor from the reactor using inert gas,
e) introducing into the reactor a silicon compound selected from the group consisting of tetraisocyanatosilane (TICS), triisocyanatosilane, and triisocyanatomethylsilane, and optionally a catalyst, to anchor abundantly on dielectric surface while less on metal surface;
f) purging any unreacted silicon compound from the reactor using inert gas,
g) providing an oxygen source comprising water vapor and optionally a catalyst into the reactor, wherein the catalyst comprises a Lewis base, to form a silicon and oxygen containing dielectric film on the dielectric surface; and
h) purging reactor with purge gas.
   wherein steps c through h, or steps e through h, are repeated to get desired thickness of the silicon and oxygen containing dielectric film. The thickness of the silicon and oxygen containing dielectric film ranges from 1 Å to 1000 Å, or 1 Å to 500 Å, or 1 Å to 300 Å, or 1 Å to 200 Å, or 1 Å to 100 Å, or 1 Å to 50 Å. The deposited film can also be treated using oxidant to form silicon and oxygen containing dielectric film. In some embodiments of this invention, steps e through h are repeated to get a desired thickness, followed by an additional step i) of cleaning the metal surface via introducing a reducing agent which is selected from the group consisting of hydrogen, hydrogen plasma, ethanol or any other common reducing agents such as citric acid to provide a clean metal surface for a subsequent semi-conductor fabrication process, followed by step c to anchor fresh self-assembled monolayer (SAM) and then repeating steps e to h to get another desired thickness of silicon and oxygen containing dielectric films. In some embodiments, step c may be performed in a separate reactor, yet in another embodiments, step c may be performed in a separate reactor via liquid phase treatment to anchor SAM.

In a particular embodiment, the method described according to this invention is a thermal atomic layer deposition method for depositing a silicon oxide and a carbon doped silicon oxide comprising:
a) providing at least one substrate having both a dielectric surface and a metal surface in a reactor,
b) heating the reactor to at least one temperature ranging from ambient temperature to about 350° C. and optionally maintaining the reactor at a pressure of 100 torr or less,
c) introducing into the reactor at least one self-assembled monolayer (SAM) volatile precursor selected from the group consisting of organic thiol compounds to predominately anchor on the metal surface while not on the dielectric surface,
d) purging any unreacted precursor from the reactor using inert gas,
e) introducing into the reactor a silicon compound selected from the group consisting of tetraisocyanatosilane (TICS), triisocyanatosilane, and triisocyanatomethylsilane, and optionally a catalyst to anchor abundantly on dielectric surface while less on metal surface;
f) purging any unreacted silicon compound from the reactor using inert gas,
g) providing an oxygen source comprising water vapor and optionally a catalyst into the reactor, wherein the catalyst comprises a Lewis base, to form a silicon and oxygen containing dielectric film on the dielectric surface; and
h) purging reactor with purge gas.
   wherein steps c through h, or steps e through h, are repeated to get desired thickness. The thickness of silicon and oxygen containing dielectric film ranges from 1 Å to 1000 Å, or 1 Å to 500 Å, or 1 Å to 300 Å, or 1 Å to 200 Å, or 1 Å to 100 Å, or 1 Å to 50 Å. The deposited film can also be treated using oxidant to form silicon and oxygen containing film. In some embodiments of this invention, steps e through h are repeated to get a desired thickness, followed by an additional step i) of cleaning the metal surface via introducing a reducing agent which is selected from the group consisting of hydrogen, hydrogen plasma, ethanol or any other common reducing agents to provide a clean metal surface for a subsequent semi-conductor fabrication process, followed by step c to anchor fresh self-assembled monolayer (SAM) and then repeating steps e to h to get another desired thickness of silicon and oxygen containing dielectric films. In some embodiments, step c may be performed in a separate reactor, yet in another embodiments, step c may be performed in a separate reactor via liquid phase treatment to anchor SAM.

The metal surface can be selected from cobalt, aluminum, copper, tantalum, ruthenium, molybdenum, tungsten or combination thereof while dielectric layer can be selected from silicon oxide, carbon doped silicon oxide, silicon oxynitride, carbon doped oxynitride, silicon nitride, and metal oxide such as zirconium oxide, hafnium oxide, silicon doped zirconium oxide, silicon doped hafnium oxide, or any other high k materials.

The volatile organic thiol compound is selected to ensure the SAM layer is stable up to 250° C., up to 150° C. or up to 125° C. insomuch that the temperature is suitable for the growth of silicon and oxygen containing dielectric film and has at least one SH group selected from RSH, R—S—S—R, and HS—R¹—SH wherein R and R¹ are independently selected from a C₁ to C₂₀ linear alkyl group, a branched C₃ to Co alkyl group, a C₃ to C₂₀ cyclic alkyl group, a C₃ to Co heterocyclic group, a C₃ to Co alkenyl group, a C₃ to Co alkynyl group, a C₁ to C₂₀ linear fluoroalkyl group, and a C₄ to C₂₀ aryl group. Examples of organic thiols include, but not limited to, methanethiol, ethanethiol, propanethiol, butanethiol, pentanethiol, hexanethiol, octanethiol, nonanethiol, decanethiol, undecanethiol, 1-dodecanethiol, 1-dodecanethiol, 1-nonanethiol, 1-decanethiol, 1-octanethiol, 1-heptanethiol, 1-hexanethiol, 1-pentanethiol, perfluorodecanethiol, di-tert-butyl disulfide, di-heptane disulfide, 2-Propene-1-thiol, tetrahydro-2H-pyran-4-thiol, 4-methyl-6-trifluoromethyl-pyrimidine-2-thiol, ara-xylene-alpha-thiol, 4-trifluoromethylbenzyl mercaptan, 4-(trifluoromethoxy)benzyl mercaptan, 4-fluorobenzyl mercaptan, 3,5-Bis(trifluoromethyl)benzenethiol, 2-(Trifluoromethyl)benzenethiol, 4-trifluoromethyl-2,3,5,6-tetrafluorothiophenol, 3,5-difluorobenzyl mercaptan, 4-trifluoromethyl-2,3,5,6-tetrafluorothiophenol, and thiophenol. In some embodiments, the volatile organic thiol is introduced into a chamber via vapor phase to anchor SAM on the surface. In other embodiments, the volatile organic thiol is introduced into a chamber via solution phase with or without solvent to anchor SAM on the surface.

In a still further embodiment of the method described herein, the film or the as-deposited silicon and oxygen containing dielectric film deposited from this invention may be subjected to a treatment step (post deposition). The treatment step can be conducted during at least a portion of the deposition step, after the deposition step, and combinations thereof. Exemplary treatment steps include, without limitation, treatment with an oxidizer/oxygen source at temperature from 100 to 800° C.; treatment via high temperature thermal annealing; plasma treatment; ultraviolet (UV) light treatment; laser; electron beam treatment and combinations thereof to affect one or more properties of the film. The oxidizer/oxygen source can be selected from hydrogen peroxide, ozone, water vapor, water vapor plasma, oxygen plasma, nitrous oxide plasma, carbon dioxide plasma or combinations thereof. The plasma is preferably remote plasma.

In another embodiment, a vessel or container for depositing a silicon and oxygen-containing film comprising one or more silicon precursor compounds described herein. In one particular embodiment, the vessel comprises at least one pressurizable vessel (preferably of stainless steel having a design such as disclosed in U.S. Pat. Nos. 7,334,595; 6,077,356; 5,069,244; and 5,465,766 the disclosure of which is hereby incorporated by reference. The container can comprise either glass (borosilicate or quartz glass) or type 316, 316L, 304 or 304L stainless steel alloys (UNS designation S31600, S31603, S30400 S30403) fitted with the proper valves and fittings to allow the delivery of one or more precursors to the reactor for a CVD or an ALD process. In this or other embodiments, the silicon precursor is provided in a pressurizable vessel comprised of stainless steel and the purity of the precursor is 98% by weight or greater or 99.5% or greater which is suitable for the majority of semiconductor applications. The head-space of the vessel or container is filled with inert gases selected from helium, argon, nitrogen and combination thereof.

After the silicon dielectric deposition process reaches the desired thickness on the dielectric surface with little or no deposition on the metal, the surfaces may be treated to improve the quality of the as-deposited dielectric film and/or to provide clean the metal surface. These post-treatments can include, but not limited to thermal treatments; plasma treatments such as helium, argon; exposure to radiation (such as ultraviolet light); and exposure to reactive reducing gases and vapors.

The substrate may be any substrate known to one of skill in the art. In one or more embodiments, the substrate comprises one or more semiconductor material, e.g., silicon (Si), silicon oxide (SiO₂), germanium (Ge), silicon germanium (SiGe), galloum arsenide (GaAs), indium phosphorus (InP), indium galloum arsenide (InGaAs), indium aluminum arsenide (InAIAs), molybdenum disulfide (MoS₂), molybdenum diselenide (MoSe₂), tungsten disulfide (WS₂), tungsten diselenide (WSe₂), titanium nitride (TiN), tantalum nitride (TaN), tungsten (W), platinum (Pt), or iridium (Ir). In some embodiments, the substrate may comprise a spacer, a metal gate, a contact, or the like. Thus, in one or more embodiments, the substrate may comprise a semiconductor material including, but not limited to, copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), zirconium (Zr), silicon carbonitride (SiCN), silicon oxycarbide (SiOC), silicon nitride (SiN), tungsten carbide (WC), tungsten oxide (WOx), silicon oxycarbonitride (SiONC), or any semiconductor substrate material known to one of skill in the art.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

The invention will be illustrated in more detail with reference to the following Examples, but it should be understood that it is not deemed to be limited thereto.

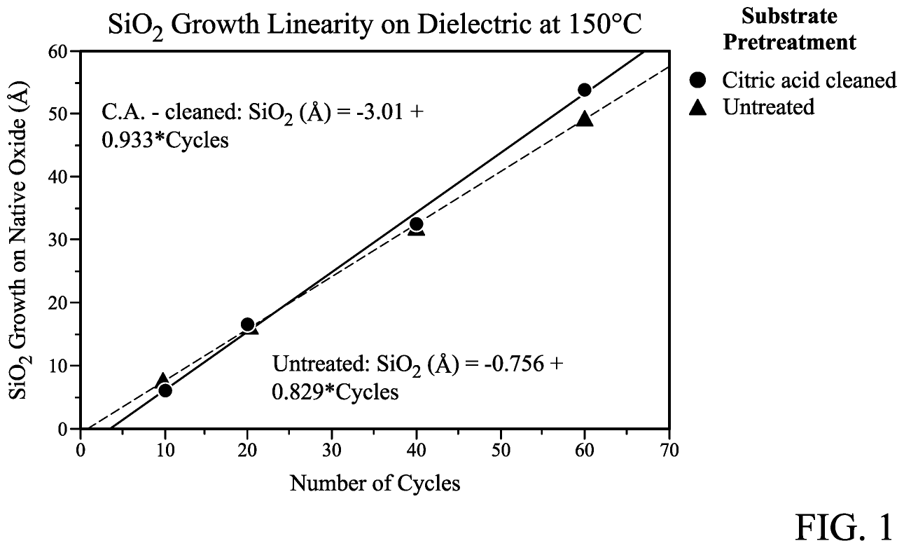

EXAMPLE 1 Thermal ALD of silicon oxide using tetraisocynatosilane, water and trimethylamine. The following thermal ALD process conditions were conducted at substrate temperature of 150° C.: As shown in FIG. 1, a linear growth behavior of silicon oxide was obtained, demonstrating the process is a typical ALD.
TICS source temperature tuned at 45-65° C., pulse time fixed at 2 sec each
H₂O and trimethylamine pulse time 0.015 s each (estimated 1.5% H₂O)
TICS 60 s trap—15 s purge—(H₂O+ trimethylamine) 60 s co-trap—15 s purge
Peak pressure during H₂O and trimethylamine co-trapping up to 600 Torr

EXAMPLE 2 Area-selective deposition of silicon oxide using SAM.

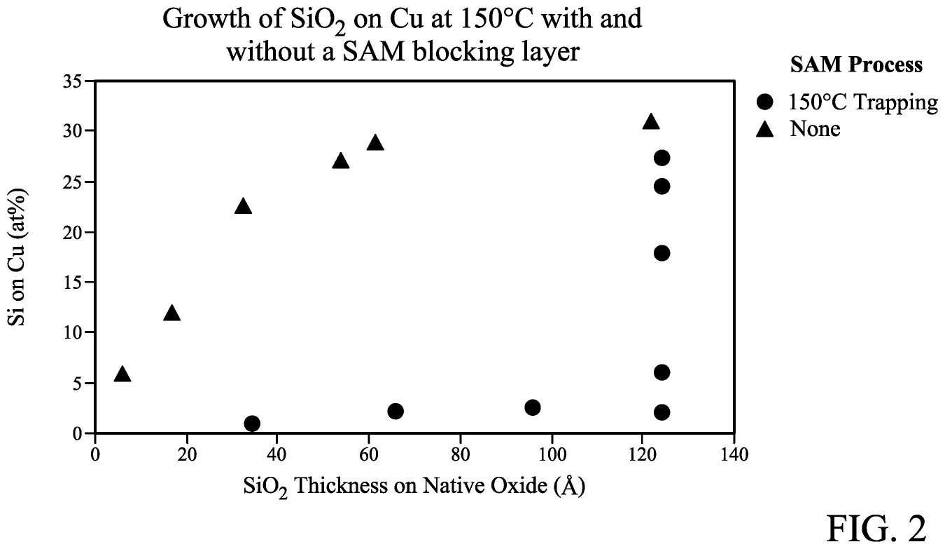

The following thermal ALD process conditions were conducted:
SAM precursor: 1-dodecanethiol
Untreated vs. citric acid cleaned native oxide and Cu substrates
Target SiO₂ thickness on native oxide: 10 nm unless noted otherwise
Selectivity is expressed by XPS Si at % on Cu/SAM due to difficulty to measure SiO₂ thickness on Cu
Goal is to minimize XPS Si on Cu/SAM1 substrate
Major factors that could affect selectivity
   SAM grafting conditions: 125° C. non-trapping vs. 150° C. trapping, 10 minutes grafting each
   SiO₂ deposition temperature: 60-150° C.
   SiO₂ trap time affects growth rate, precursor and co-reactant diffusion into SAM layer
   SiO₂ purge time affects physical desorption of TICS and/or H₂O/trimethylamine co-reactants
   30 s vs. 15 s trap time with variable purge time
   20 sccm N₂ flow, base pressure ˜0.35 Torr
   As shown in FIG. 2, there is a clear selectivity with SAM blocking SiO₂ growth on Cu when SiO₂ thickness on native oxide is below 120 Å.

1. A thermal atomic layer deposition method for selectively depositing a silicon and oxygen containing film into surface features on a substrate, the method comprising:
a) providing at least one substrate having both a dielectric surface and a metal surface in a reactor,
b) heating the reactor to at least one temperature ranging from ambient temperature to about 350° C. and optionally maintaining the reactor at a pressure of 100 torr or less,
c) introducing into the reactor at least one self-assembled monolayer (SAM) volatile precursor selected from the group consisting of organic thiol compounds to anchor more abundantly on the metal surface than on the dielectric surface,
d) purging the reactor using inert gas,
e) introducing into the reactor a silicon compound selected from the group consisting of tetraisocyanatosilane (TICS), triisocyanatosilane, and triisocyanatomethylsilane, and optionally a catalyst, to anchor the silicon compound more abundantly on the dielectric surface than on metal surface;
f) purging the reactor using inert gas,
g) providing an oxygen source and optionally a catalyst into the reactor, wherein the catalyst comprises a Lewis base, to form a silicon and oxygen containing dielectric film on the dielectric surface; and
h) purging the reactor using inert gas.

2. The method of claim 1 wherein the dielectric surface is selected from the group consisting of silicon oxide, carbon doped silicon oxide, silicon oxynitride, carbon doped oxynitride, silicon nitride, and metal oxide.

3. The method of claim 1 wherein the metal surface includes at least one metal selected from the group consisting of cobalt, aluminum, copper, tantalum, ruthenium, manganese, molybdenum, tungsten and combination thereof.

4. The method of claim 1 wherein the organic thiol compound is selected from the group consisting of methanethiol, ethanethiol, propanethiol, butanethiol, pentanethiol, hexanethiol, octanethiol, nonanethiol, decanethiol, undecanethiol, 1-dodecanethiol, 1-dodecanethiol, 1-nonanethiol, 1-decanethiol, 1-octanethiol, 1-heptanethiol, 1-hexanethiol, 1-pentanethiol, perfluorodecanethiol, di-tert-butyl disulfide, di-heptane disulfide, 2-Propene-1-thiol, tetrahydro-2H-pyran-4-thiol, 4-methyl-6-trifluoromethyl-pyrimidine-2-thiol, ara-xylene-alpha-thiol, 4-trifluoromethylbenzyl mercaptan, 4-(trifluoromethoxy)benzyl mercaptan, 4-fluorobenzyl mercaptan, 3,5-bis(trifluoromethyl)benzenethiol, 2-(trifluoromethyl)benzenethiol, 4-trifluoromethyl-2,3,5,6-tetrafluorothiophenol, 3,5-difluorobenzyl mercaptan, 4-trifluoromethyl-2,3,5,6-tetrafluorothiopheno, and thiophenol.

5. The method of claim 1 wherein the oxygen source comprises water.

6. The method of claim 1, wherein the catalyst is provided into the reactor in step g).

7. The method of claim 6 wherein the catalyst is selected from the group consisting of trimethylamine, triethylamine, tri-n-propylamine, tri-iso-propylamine, tri-n-butylamine, phenyldimethylamine, tri-iso-butylamine, pyridine, and piperazine.

8. The method of claim 6, wherein the oxygen source and the catalyst are mixed prior to be provided into the reactor in step g).

9. The method of claim 1, wherein the silicon and oxygen containing film is selected from the group consisting of silicon oxide film, silicon oxynitride film, carbon doped silicon oxide film, and carbon doped silicon oxynitride film.

10. The method of claim 2, wherein the metal oxide is selected from the group consisting of zirconium oxide, hafnium oxide, silicon doped zirconium oxide, and silicon doped hafnium oxide.
